(19) United States
(12) Patent Application Publication
(10) Pub. No.: US 2018/0166614 A1
(43) Pub. Date: Jun. 14, 2018

(54) METHOD OF PRODUCING A CONVERTER COMPONENT

(71) Applicant: OSRAM Opto Semiconductors GmbH, Regensburg (DE)

(72) Inventors: Markus Richter, Burglengenfeld (DE); Martin Brandl, Kelheim (DE); Markus Burger, Laaber (DE); Günter Spath, Regensburg (DE)

(73) Assignee: OSRAM Opto Semiconductors GmbH, Regensburg (DE)

(21) Appl. No.: 15/571,084

(22) PCT Filed: May 4, 2016
(86) PCT No.: PCT/EP2016/060054

§ 371 Date: Nov. 1, 2017

(30) Foreign Application Priority Data
May 4, 2015 (DE) 10 2015 106 865.6

(51) Int. Cl. H01L 33/50; B29D 11/00

(52) U.S. Cl. CPC H01L 33/505; B29D 11/00798; H01L 2933/0041; H01L 33/56; H01L 2933/005; H01L 33/507; H01L 2933/0091

(57) ABSTRACT

A method of producing a converter component for an optoelectronic lighting apparatus includes forming a layer stack having an injection-molded or extruded conversion layer and an injection-molded or extruded diffuser layer. A converter component for an optoelectronic lighting apparatus includes a layer stack including an injection-molded or extruded conversion layer, and an injection-molded or extruded diffuser layer.

### TECHNICAL FIELD

This disclosure relates to a method of producing a converter component for an optoelectronic lighting apparatus, a converter component and an optoelectronic lighting apparatus.

### BACKGROUND

For flash applications, a requirement for a highly homogeneous appearance of the flash LED in the deactivated state is important. LED stands for “light-emitting diode.”

Generally, a deactivated LED is to appear completely white, without an LED substrate, a bonding wire, a chip, or a conversion layer being visible.

For this purpose, on the one hand, it is necessary to embed the substrate, chip, and wire in a white material (for example, via potting with silicone having a highly reflective filler or via molding into a white housing material).

If the conversion layer on the LED chip is not to be apparent, a diffuse diffusing layer must be applied to the LED chip.

As mentioned above, the substrate, a wire possibly present (if no flip chip is used), and the chip are generally covered via potting with white potting material (alternatively, molding with a highly reflective molding compound, for example, via film-assisted transfer molding). However, until now, it has only been possible to pot up to the upper edge of the chip or insert ceramic conversion plates (a diffuse layer must then likewise be applied to them) having sharp stop edges for the potting compound/molding compound.

It could therefore be helpful to provide a reproducible and homogeneous appearance of a converter component and an efficient suitability of the converter component for a potting process.

### SUMMARY

We provide a method of producing a converter component for an optoelectronic lighting apparatus including forming a layer stack having an injection-molded or extruded conversion layer and an injection-molded or extruded diffuser layer.

We also provide a converter component for an optoelectronic lighting apparatus including a layer stack including an injection-molded or extruded conversion layer, and an injection-molded or extruded diffuser layer.

We further provide an optoelectronic lighting apparatus including a light-emitting semiconductor component and the converter component for an optoelectronic lighting apparatus including a layer stack including an injection-molded or extruded conversion layer, and an injection-molded or extruded diffuser layer.

### BRIEF DESCRIPTION OF THE DRAWINGS

FIGS. 1 to 7 respectively show a production step in a method of producing a first converter component.

FIGS. 8 to 12 respectively show a production step in a method of producing a second converter component.

FIGS. 13 to 20 respectively show a production step in a method of producing a third converter component.

FIG. 21 shows a production step in a method of producing a fourth converter component.

FIGS. 22 to 27 respectively show a production step in a method of producing a fifth converter component.

FIG. 28 shows a step in a method of producing a sixth converter component.

FIG. 29 shows a flow chart of a method of producing a converter component.

FIG. 30 shows an optoelectronic lighting apparatus.

FIG. 31 shows a schematic representation of an extrusion process in a lateral sectional view.

FIG. 32 shows a schematic representation of the extrusion process of FIG. 31 in a top view.

### LIST OF REFERENCE NUMBERS

101 Carrier
103 Surface of the carrier
105 Clamping ring
201 Injection-molding tool
203 Lower part
205 Upper part
207 Cavity insert
209 Sealing frame
211 Seal
213 Cavity insert clamp
215 Spring
217 Anti-adhesion film
219 Conversion material
301 Injection-molded conversion layer
501 Surface of the conversion layer
601 Extruded diffuser layer
701 Roller
703 Direction of motion of the roller
705 Converter component
801 Surface of the diffuser layer
1201 Converter component
1301 Diffuser material
1401 Injection-molded diffuser layer
1501 Surface of the diffuser layer
2001 Converter component
2101 Extruded conversion layer
2103 Converter component
2401 Surface of the extruded conversion layer
2701 Converter component
2801 Converter component
2901 Forming
3001 Optoelectronic lighting apparatus
3003 Light-emitting semiconductor component
3005 Converter component with removed carrier
3007 Primary radiation
3009 Secondary radiation
3101 Film
3103 Film
3105 Film
3107 Direction of motion
3109 Extrusion tool
3111 Hollow body
3113 Upper side of the hollow body
3115 Lower side of the hollow body
3117 Conversion material
3119 Conversion layer

### DETAILED DESCRIPTION

Our method of producing a converter component for an optoelectronic lighting apparatus may comprise the following step:
forming a layer stack having an injection-molded or extruded conversion layer and an injection-molded or extruded diffuser layer.

Additionally, a converter component for an optoelectronic lighting apparatus may comprise:
a layer stack including
an injection-molded or extruded conversion layer, and
an injection-molded or extruded diffuser layer.

An optoelectronic lighting apparatus may comprise:
a light-emitting semiconductor component, and
the converter component for an optoelectronic lighting apparatus.

We provide a converter component having a layer stack, wherein the layer stack comprises an injection-molded or extruded conversion layer and an injection-molded or extruded diffuser layer. This means in particular that the conversion layer of the layer stack is an injection-molded or extruded conversion layer. This means in particular that the diffuser layer of the layer stack is an injection-molded or extruded diffuser layer. This means in particular that the conversion layer is injection-molded or extruded. This means in particular that the diffuser layer is injection-molded or extruded. This means in particular that the conversion layer is produced by injection molding or an injection-molding process or by extrusion or an extrusion process. This means in particular that the diffuser layer is produced by injection molding or an injection molding process or by an extrusion process or extrusion.

By providing such layers for the layer stack, in particular the technical advantage is achieved that homogeneous layer thicknesses may be obtained based on the injection-molding technology or the extrusion technology. In particular, a surface of such formed layers may be produced to be particularly smooth. Thus, in particular the technical advantage is achieved that a layer thickness of the layer stack may be reproduced.

By providing such a converter component in an optoelectronic lighting apparatus, furthermore, the technical advantage may be achieved that in a deactivated operating state of the light-emitting semiconductor component, an optical impression or an optical appearance is created that corresponds to the optical impression or the optical appearance of the diffuser layer. Depending on the color of the diffuser layer, in particular a certain color impression of the light-emitting semiconductor component in a deactivated state may thus be achieved in an advantageous manner. The color may, for example, be white.

In particular, due to the layer stack, an efficient component-specific packaging is achieved. Due to the use of two layers for the layer stack, layer thicknesses corresponding to the component requirements, the converters used, and the chromaticity points to be produced may be correspondingly adjusted in an advantageous manner. Thus, there is high flexibility with respect to a layer thickness for the layer stack. Thus, for example, layer stacks may have an identical thickness at different chromaticity points, the chromaticity points generally being achieved by different layer thicknesses of the conversion layer. The collective thickness of the layer stacks may then, for example, be achieved by corresponding adjustment of the layer thickness of the diffuser layer.

In addition, such a layer stack may be efficiently singulated to form singulated layer stacks on a shared carrier so that, for example, very high contour accuracy may be achieved. In particular, stop edges for subsequent potting processes may be efficiently produced. In particular, a rapid adjustment to desired dimensions may be carried out.

The conversion layer may be free from a surface topography.

The diffuser layer may be free from a surface topography.

Free from a surface topography means in particular that the diffuser layer or the conversion layer is free from a surface structure. A surface of the diffuser layer or the conversion layer thus has no surface topography or has no surface structure.

A particular advantage of the injection-molding technology or the extrusion technology is in particular apparent in that a surface of a correspondingly produced layer is smoother than is the case, for example, in a layer produced by a pressure process, for example, a squeegee pressure process, or dispensing.

In particular, dispensing generally has a meandering pattern. Thus, meandering surface structures may be found on dispensed layers. However, this is not the case with extruded or injection-molded layers.

A fluctuation in thickness of the conversion layer or diffuser layer may be a maximum of 5 μm. This means in particular that a thickness of the conversion layer or the diffuser layer varies at most within a range of 5 μm.

Thus, as a result of an extruded conversion layer or injection-molded conversion layer having a relatively constant thickness, a chromaticity point of the light converted by the conversion layer may be efficiently and precisely adjusted.

The conversion layer may be free from an Aerosil. The diffuser layer may be free from an Aerosil.

In a dispensing or squeegee pressure process, the pressure materials used therefor are generally Aerosils to adjust a certain viscosity of the pressure material to prevent a sedimentation of diffuser particles or phosphor particles in a pressure cartridge.

This is not necessary in an extrusion process or an injection-molding process. Thus, an Aerosil may be dispensed with here. Thus, a diffuser layer or a conversion layer produced by an extrusion process or an injection-molding process differs from a diffuser layer or a conversion layer produced by a squeegee pressure method or by dispensing, in particular in that the latter comprise layers of Aerosil. In contrast, according to one example, the former do not.

Injection molding may comprise compression molding. This means in particular that in one example, the injection-molded diffuser layer or conversion layer is a compression-molded diffuser layer or a compression-molded conversion layer.

The carrier may be a film, for example, a polyimide film, a polytetrafluoroethylene film, a UV film, a sawing film, a so-called “thermal-release film” (an adhesive film which may be detached by heating the object (here, the layer stack) onto which the adhesive film is also bonded).

In an extrusion process, i.e., in an extrusion method, a diffuser material or a conversion material on the carrier, which is in particular a film, may be applied by a tool, in particular to be cast on the carrier, while the carrier moves relative to the tool. The tool is, for example, held in a fixed, i.e., stationary, position during the application, i.e., it is not moved during the application. For example, the film is drawn under the tool via one or more rollers, while the diffuser material or the conversion material is applied to the film, in particular is cast, by the tool.

The tool, which may also be referred to as an extrusion tool, is, for example, configured as a hollow body open on two opposite sides so that the conversion material or the diffuser material may be introduced into the hollow body on the one side so that the introduced conversion material or the introduced diffuser material may escape from the tool via the other side to thus be applied to, in particular cast on, the carrier, in particular the film.

Application of a conversion material or a diffuser material to the carrier within the scope of an extrusion process comprises in particular casting the conversion material or the diffuser material on the carrier.

The carrier is, for example, formed from tinplate or comprises, for example, tinplate.

A thickness of the carrier is, for example, 50 μm to 500 μm.

The carrier is in particular a temporary carrier and is, for example, again removed in a later method step.

A layer stack thus comprises in particular multiple layers, in particular exactly two layers, here in particular the conversion layer and the diffuser layer stacked one above the other. This means that the individual layers of the layer stack are stacked.

A conversion layer is configured to convert electromagnetic radiation having a first wavelength or a first wavelength range into electromagnetic radiation having a second wavelength or a second wavelength range, wherein the second wavelength is different from the first wavelength, or the second wavelength range is at least partially, in particular completely, different from the first wavelength range. A conversion layer thus has a converter function or a conversion function, i.e., it converts electromagnetic radiation. The electromagnetic radiation to be converted may, for example, be referred to as primary light or primary radiation. The electromagnetic radiation converted by the conversion layer may, for example, be referred to as secondary light or secondary radiation.

Due to the conversion function, a conversion layer may also be referred to as a converter layer.

The primary radiation lies, for example, in the range of 430 nm to 480 nm.

The secondary radiation lies, for example, in the range of 450 nm to 800 nm.

To form a layer stack having an injection-molded conversion layer and an extruded diffuser layer, a conversion material may be arranged on a surface of a carrier by injection molding to form an injection-molded conversion layer arranged on the surface of the carrier, wherein an extruded diffuser layer is laminated onto the injection-molded conversion layer arranged on the surface of the carrier.

This means in particular that the conversion layer is injection-molded, whereas the diffuser layer is extruded or gets extruded. The diffuser layer is laminated onto the injection-molded conversion layer.

Extrusion or extruding a diffuser layer and/or a conversion layer generally has in particular the advantage that a large quantity of diffuser layer and/or conversion layer may be efficiently produced. For example, a large quantity may comprise a length of 200 m. For example, a large quantity may comprise a width of 0.8 m. This means that in particular a diffuser layer and/or a conversion layer having a length of, for example, 200 m, and having a width of, for example, 0.8 m, may be efficiently produced. Subsequently, for example, cutting to shorter lengths and/or shorter widths may take place in an advantageous manner.

An injection mold or injection molding of a conversion layer and/or a diffuser layer in particular generally has the advantage that a very flexible adjustability of a layer thickness of the diffuser layer and/or the conversion layer is made possible. The layer thickness may, for example, be adjusted by adjusting the fed-in quantity of diffuser material and/or conversion material (for example, a silicone comprising a phosphor). Furthermore, a phosphor content or a phosphor concentration in the conversion layer may be flexibly adjusted in an injection-molding process or in an injection-molding method. This is in particular also carried out by adjusting the fed-in quantity of conversion material comprising a phosphor. In particular if the diffuser layer and/or the conversion layer is to have a thickness greater than, or greater than or equal to, 200 μm, an injection-molding method is particularly advantageous and efficient.

Provision of a carrier generally has the technical advantage that an efficient transport of the layer or layers arranged on the surface of the carrier may be carried out. Thus, for example, the carrier may be introduced into an injection-molding tool to form an injection-molded layer by injection molding. Subsequently, the carrier having the injection-molded layer may be removed from the injection-molding tool to transport the carrier to a laminating apparatus. By the carrier, simple handling of the layer or the layers is achieved. These advantages of the carrier apply analogously to additional examples comprising such a carrier, even if this is not explicitly acknowledged in the corresponding places.

One example provides for a carrier having a carrier surface. One example provides a carrier having a carrier surface.

The carrier is, for example, clamped in a clamping ring or gets clamped in a clamping ring. Such a clamping ring having a clamped carrier may be arranged on, or attached to, an upper part of an injection-molding tool.

To form a layer stack having an injection-molded conversion layer and an extruded diffuser layer, an extruded diffuser layer may be laminated onto a surface of a carrier, wherein a conversion material is arranged by injection molding on the diffuser layer laminated on the surface of the carrier to form an injection-molded conversion layer arranged on the diffuser layer.

This means in particular that the diffuser layer is laminated onto the surface of the carrier, wherein the conversion layer is then applied by injection molding to the diffuser layer.

To form a layer stack having an injection-molded conversion layer and an injection-molded diffuser layer, a diffuser material may be arranged on a surface of a carrier by injection molding to form an injection-molded diffuser layer arranged on the surface of the carrier, wherein a conversion material is arranged by injection molding on the injection-molded diffuser layer arranged on the surface of the carrier to form an injection-molded conversion layer arranged on the diffuser layer.

This means in particular that both layers of the layer stack are injection-molded. In this case, initially, the diffuser layer is applied by injection molding to the carrier, and only then is the conversion layer applied by injection molding to the diffuser layer which has been thus injection-molded. One advantage of this example is in particular that a production process purely via compression molding (injection molding) is highly flexible. Thus, thicknesses of the conversion layer/diffuser layer, as well as diffuser content and phosphor content, may be flexibly adjusted from shot to shot (from injection molding to injection molding).

To form a layer stack having an extruded conversion layer and an injection-molded diffuser layer, a diffuser material may be arranged on a surface of a carrier by injection molding to form an injection-molded diffuser layer arranged on the surface of the carrier, wherein an extruded conversion layer is laminated onto the injection-molded diffuser layer arranged on the surface of the carrier.

This means in particular that the diffuser layer is initially injection-molded onto the surface, wherein the conversion layer is then laminated onto the injection-molded diffuser layer. If the conversion layer is produced via film lamination (extrusion), significantly thinner layer thicknesses (at least 30 μm) may be achieved for the conversion layer. A layer thickness is of course in particular a function of a phosphor particle size (the term “phosphor” means “luminescent material”). The layer thickness of the conversion film (or conversion layer) is, for example, approximately three times (3X) the phosphor particle size. The molding (injection molding) of the diffuser layer is less critical, since the diffuser particles are generally very small (<1 μm). Therefore, it is also possible to mold (injection molding) diffuser layer thicknesses of 50 μm. However, a typical mold thickness (diffuser layer thickness) may also be, for example, 100 μm.

This means that an injection-molded diffuser layer, for example, has a thickness of 40 μm to 60 μm, in particular 50 μm, or a thickness of 90 μm to 110 μm, in particular 100 μm.

To form a layer stack having an extruded conversion layer and an injection-molded diffuser layer, an extruded conversion layer may be laminated onto a surface of a carrier, wherein a diffuser material is arranged by injection molding on the conversion layer laminated on the surface of the carrier to form an injection-molded diffuser layer arranged on the conversion layer.

This means in particular that the extruded conversion layer is laminated onto the surface of the carrier, wherein the diffuser layer is then injection-molded onto the laminated conversion layer. Here, in particular the same advantages apply as in the example in which the diffuser layer is injection-molded (molded) and the conversion layer is laminated.

After formation of the layer stack, the carrier may be removed from the layer stack.

As a result, in particular the technical advantage is achieved that the layer stack may still be used for an optoelectronic lighting apparatus, with no interference from the carrier. In particular, an optoelectronic characterization of the layer stack may then be advantageously carried out.

The carrier may be formed as a carrier film.

As a result, in particular the technical advantage is achieved that simple handling of the carrier is made possible due to the flexibility of the carrier film. In particular, such a carrier film may be used within the scope of a so-called “film-assisted molding” injection molding process. In this case, “film-assisted molding” stands for film-assisted injection molding.

The injection molding may be film-assisted molding.

The diffuser layer and/or the conversion layer may be formed as a diffuser film or conversion film.

As a result of the provision of a diffuser film and/or a conversion film, in particular the technical advantage is achieved that due to the flexibility of the film(s), efficient handling of the layer stack may be achieved.

To form a layer stack having an extruded conversion layer and an extruded diffuser layer, an extruded conversion layer and an extruded diffuser layer may be laminated together.

This means in particular that the two layers of the layer stack are laminated together. One advantage in this case is that the stack (layer stack) which is made up of an extruded conversion layer (film) and a diffuse layer (extruded diffuser layer) (film) may be constructed or produced to be very thin (at least 60 μm).

A minimum layer thickness in a layer stack comprising an injection-molded conversion layer and an extruded diffuser layer may be, for example, 230 μm.

A minimum layer thickness in a layer stack comprising an extruded conversion layer and an injection-molded diffuser layer may be, for example, 80 μm.

The diffuser layer may comprise one or multiple diffuser particles, in particular: SiO₂ particles, Al₂O₃ particles, TiO₂ particles, silicone particles, glass particles. A diffuser particle may, for example, be referred to as a diffuser.

By providing one or multiple diffuser particles, in particular the technical advantage is achieved that an efficient diffusion of electromagnetic radiation is achieved. In particular, by the provision of different particle sizes, a different diffusion level or diffusion cross section may be set. For example, a diffuser particle may comprise average grain sizes of 100 nm to 10 μm. This means in particular that a diameter of the diffuser particles may be 100 nm to 10 μm.

The aforementioned materials for diffuser particles and in particular the different particle sizes advantageously have different properties which may be used according to the requirements. Thus, for example, Al₂O₃ contributes better to homogenizing the light or generally the electromagnetic radiation. TiO₂ contributes to a better white appearance in the deactivated state.

The conversion layer may comprise silicone and a converter.

A converter is in particular a material or a material composition (i.e., generally a material) that causes a conversion of electromagnetic radiation. A converter is, for example, a phosphor. A converter is, for example, an organic or an inorganic pigment. Converters are in particular powders (comprising, for example, phosphor and/or an inorganic and/or an organic phosphor) fixed in a radiation-stable matrix. Silicone is particularly suitable in the exemplary range of the primary radiation specified above as a matrix material.

This means in particular that the converter, for example, a powder, is embedded in silicone. The silicone thus forms in particular a matrix in which the powder or generally the converter is preferably embedded.

At least one of the two layers, in particular both layers, i.e., the diffuser layer and/or the conversion layer, may comprise silicone.

This means in particular that the diffuser layer may comprise a silicone. In particular, the conversion layer may comprise a silicone. The use of silicone in particular has the technical advantage that an efficient injection molding or efficient extrusion is made possible.

The conversion layer may have a layer thickness of 10 μm to 200 μm, in particular 30 μm to 200 μm.

The diffuser layer may have a layer thickness of 10 μm to 500 μm, in particular 30 μm to 500 μm.

The aforementioned layer thicknesses are in particular a function of a desired chromaticity point and/or in particular a desired overall layer thickness (thickness of the layer stack).

The light-emitting semiconductor component may be a luminescent diode. Such a luminescent diode is referred to as a light-emitting diode (LED).

The light-emitting semiconductor component may be a laser diode. In particular, multiple light-emitting semiconductor components are provided which, for example, may be formed identically or preferably differently.

This means in particular that the converter component is arranged in an emission region of the light-emitting semiconductor component(s) to convert the electromagnetic radiation emitted by the light-emitting semiconductor component(s).

Multiple converter components may be provided.

A layer (for example, conversion layer, diffuser layer) of the layer stack comprises an upper side and a lower side opposite the upper side. According to the arrangement of the layers in the layer stack among one another, the lower side of the one layer is arranged on the upper side of another layer. A position of a layer in the layer stack may, for example, be defined with reference to the carrier.

Silicones (singular silicone), chemically, poly(organo)siloxanes, is a designation for a group of synthetic polymers in which silicon atoms are bonded via oxygen atoms.

Singulation of the layer stack may be provided. The layer stack is thus in particular singulated. This means, for example, that recesses are formed in the layer stack running through the layer stack to the surface of the carrier. Thus, layer stacks are formed that are separated from each other and arranged on the common carrier. These singulated layer stacks thus form singulated converter components.

The singulation may, for example, be carried out via a saw, a laser, a water jet, and/or a die cutter.

A finished extruded diffuser layer may be used within the scope of the production method. In particular, such a diffuser layer may be extruded within the scope of the production process. The method thus may explicitly comprise the step of the extrusion of a diffuser layer.

This means that in a step of the production method (the method for production), it may be provided that the extruded diffuser layer is formed.

Extrusion may also be referred to as film drawing.

A finished extruded conversion layer may be used within the scope of the production method. In particular, such a conversion layer is extruded within the scope of the production method. The method may thus explicitly comprise the step of the extrusion, in particular the casting, of a conversion layer.

This means that in a step of the production method (the method for production), it may be provided that the extruded conversion layer is formed.

Extrusion may comprise casting.

A finished injection-molded diffuser layer may be used within the scope of the production method. In particular, such a diffuser layer may be injection-molded within the scope of the production method. The method thus explicitly comprises the step of the injection molding, in particular the compression molding, of a diffuser layer.

This means that in a step of the production method (the method for production), for example, the injection-molded diffuser layer is formed.

A finished injection-molded conversion layer may be used within the scope of the production method. In particular, such a conversion layer may be injection-molded, in particular compression-molded, within the scope of the production method. The method thus explicitly comprises the step of injection molding, in particular the compression molding, of a conversion layer.

This means that in a step of the production method (the method for production), for example, the injection-molded conversion layer is formed.

Injection molding comprises in particular compression molding.

Injection molding, in particular compression molding, comprises in particular a use of an injection-molding tool comprising a lower part and an upper part. It is in particular provided that a carrier, in particular a carrier having a layer already arranged on the carrier; in particular a diffuser layer or a conversion layer, is arranged in the lower part or the upper part. In particular after this arrangement, the injection-molding tool is closed, i.e., the lower part and the upper part are brought together, wherein subsequently, a conversion material or a diffuser material is introduced into the injection-molding tool to accordingly form a diffuser layer or conversion layer.

The converter component for an optoelectronic lighting apparatus may be produced or gets produced by the method of producing a converter component for an optoelectronic lighting apparatus.

The layer stack may be arranged or formed on the surface of a carrier.

Examples relating to the converter component result analogously from the corresponding examples of the method, and vice-versa. This means that technical functionalities for the converter component result from corresponding technical functionalities of the method, and vice-versa.

The above-described properties, features and advantages, as well as the manner in which they are achieved, will become clearer and more readily comprehensible in conjunction with the following description of the examples explained in conjunction with the drawings.

Identical reference numerals may be used below for identical features.

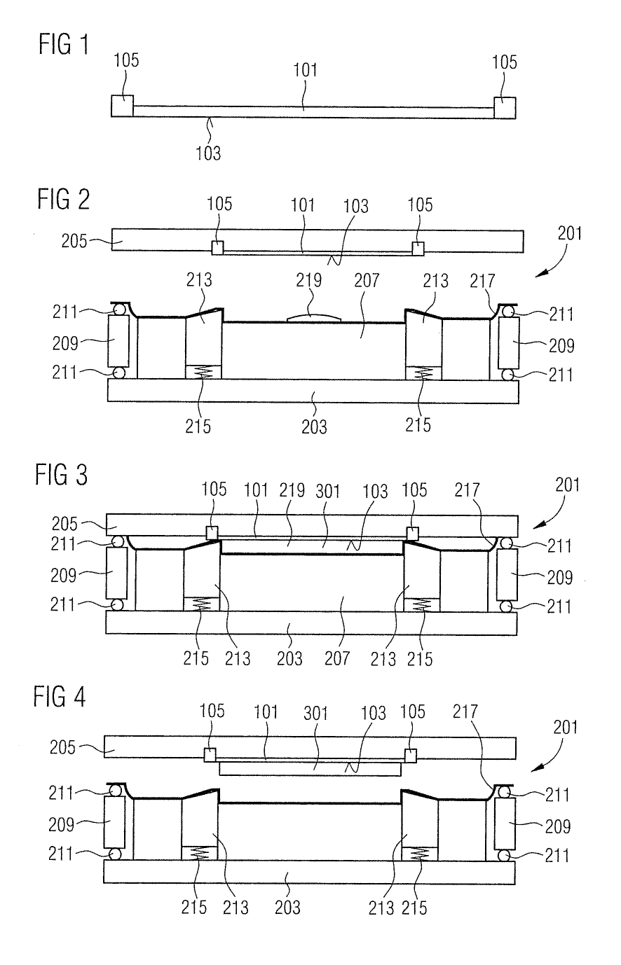

FIG. 1 shows a carrier 101 in a lateral sectional view. The carrier 101 may, for example, be formed as a carrier film. The carrier 101 may, for example, be formed from the following material or may comprise the following materials: polyimide, polytetrafluoroethylene, UV film, sawing films, thermal release foil, metal sheet.

The carrier 101 has a surface 103. The carrier 101 is clamped into a clamping ring 105 so that the carrier 101 may be displaced or moved by displacing or moving the clamping ring 105.

FIG. 2 shows an injection-molding tool 201 comprising a lower part 203 and an upper part 205, in a lateral sectional view. The carrier 101 is arranged on the upper part 205. This is done by attaching the clamping ring 105 to the upper part 205. If the upper part 205 and the lower part 203 of the injection-molding tool 201 are combined, a cavity is thereby formed, in which according to FIG. 2, a cavity insert 207 is inserted. FIG. 2 shows the injection-molding tool 201 in an open state.

A sealing frame 209 is provided enclosing the cavity insert 207, wherein seals 211 are formed that hermetically seal the cavity in the closed state of the injection-molding tool 201.

Furthermore, a respective cavity insert clamp 213 is provided next to the cavity insert 207 on the left and right. The cavity insert clamps 213 are respectively pressurized by a spring force generated by a spring 215. This means that in a closed state of the injection-molding tool 201, by the springs 215, an elastic spring tension acts on the upper part 205 via the cavity insert clamps 213.

An anti-adhesion film 217 is arranged on the surface of the lower part 203 facing the upper part 205. The anti-adhesion film may, for example, comprise ethylene tetrafluoroethylene or may be formed from ethylene tetrafluoroethylene.

A conversion material 219 is applied to the anti-adhesion film 217. The anti-adhesion film 217 prevents an adhesion of the conversion material 219 to the surface of the lower part 203.

The injection-molding process or the injection-molding method carried out by the injection-molding tool 201 generally is or comprises (i.e., also in particular detached from this example) in particular a compression molding process or a compression molding method. Therefore, injection molding may generally in particular comprise compression molding or may be referred to as compression molding. “Injection-molded” may then, for example, generally comprise “compression-molded” or may be referred to as “compression-molded.”

FIG. 3 shows the injection-molding tool 201 in a closed state. This means that the lower part 203 and the upper part 205 approach one another and close. Thus, an injection-molding process takes place which is known per se, here in particular film-assisted molding or film-assisted injection molding. This means that an injection-molded conversion layer 301 is formed from the introduced conversion material 219. Thus, an injection-molded conversion layer 301 is formed on the surface 103 of the carrier 101 during the injection molding.

FIG. 4 shows the injection-molding tool 201 in an open or opened state after the injection molding.

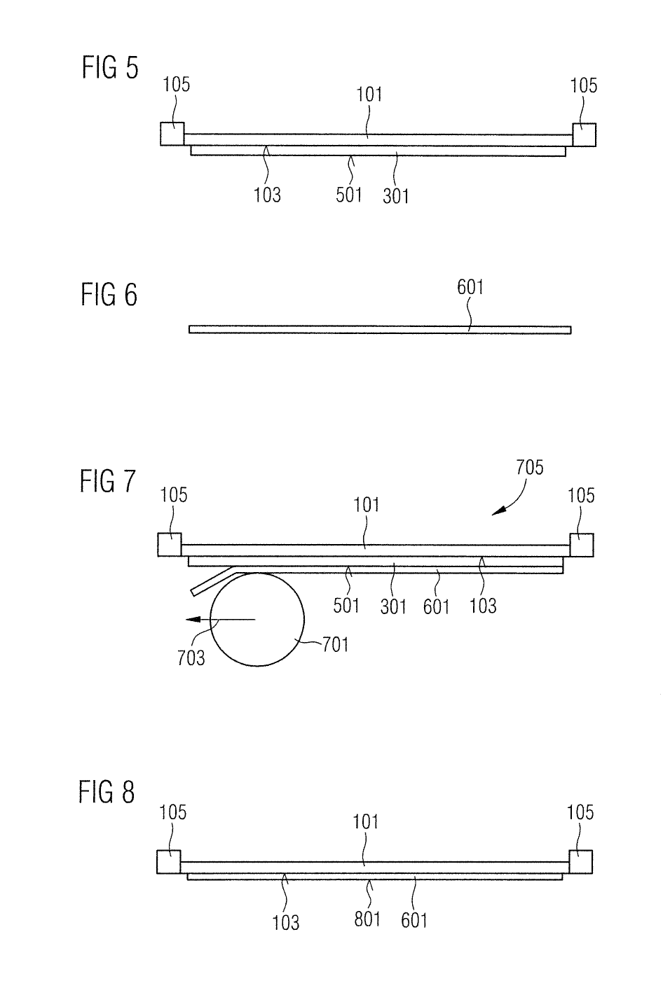

FIG. 5 shows the clamping ring 105 comprising the clamped carrier 101 after removing the clamping ring 105 from the upper part 205 of the injection-molding tool 201. The injection-molded conversion layer 301, which, for example, may be formed as an injection-molded conversion film, is apparent. The injection-molded conversion layer 301 comprises a surface 501 facing away from the surface 103 of the carrier 101.

FIG. 6 shows an extruded diffuser layer 601. The extruded diffuser layer 601 may already be finished. In another example, the method comprises such an extruded diffuser layer being produced.

This extruded diffuser layer 601 is laminated onto the surface 501 of the conversion layer 301, as FIG. 7 shows. A roller 701 is provided which presses the diffuser layer 601 onto the surface 501 for the purpose of laminating. A direction of motion of the roller 701 during lamination is indicated by an arrow having the reference numeral 703.

Thus, a converter component 705 is formed. The converter component 705 comprises a layer stack comprising the injection-molded conversion layer 301 and the extruded diffuser layer 601. In an example not shown, this layer stack is removed from the carrier 101.

FIGS. 8 to 12 respectively show a production step in a method of producing a second converter component.

FIG. 8 shows the clamped carrier 101 analogously to FIG. 1, wherein here, an extruded diffuser layer 601 which, for example, may be formed as an extruded diffuser film, is already laminated on the surface 103 of the carrier 101. This means in particular that the method may comprise production of an extruded diffuser layer. In particular, the method comprises lamination of such an extruded diffuser layer onto the surface 103 of the carrier 101.

The diffuser layer 601 has a surface 801 facing away from the surface 103.

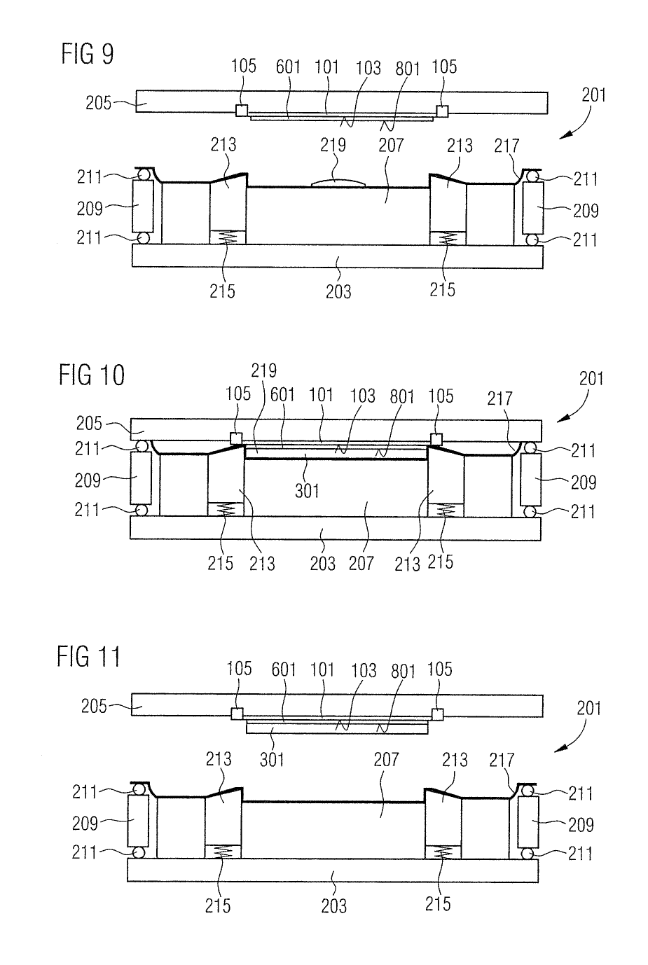

FIGS. 9 to 11 show, analogously to FIGS. 2 to 4, an injection-molding process of producing an injection-molded conversion layer. This means that according to FIG. 9, the clamped carrier 101 having the laminated diffuser layer 601 is arranged on the upper part 205 of the injection-molding tool 201. Analogously to FIG. 2, a conversion material 219 is arranged on the anti-adhesion film 217 to accordingly form an injection-molded conversion layer 301 on the surface 801.

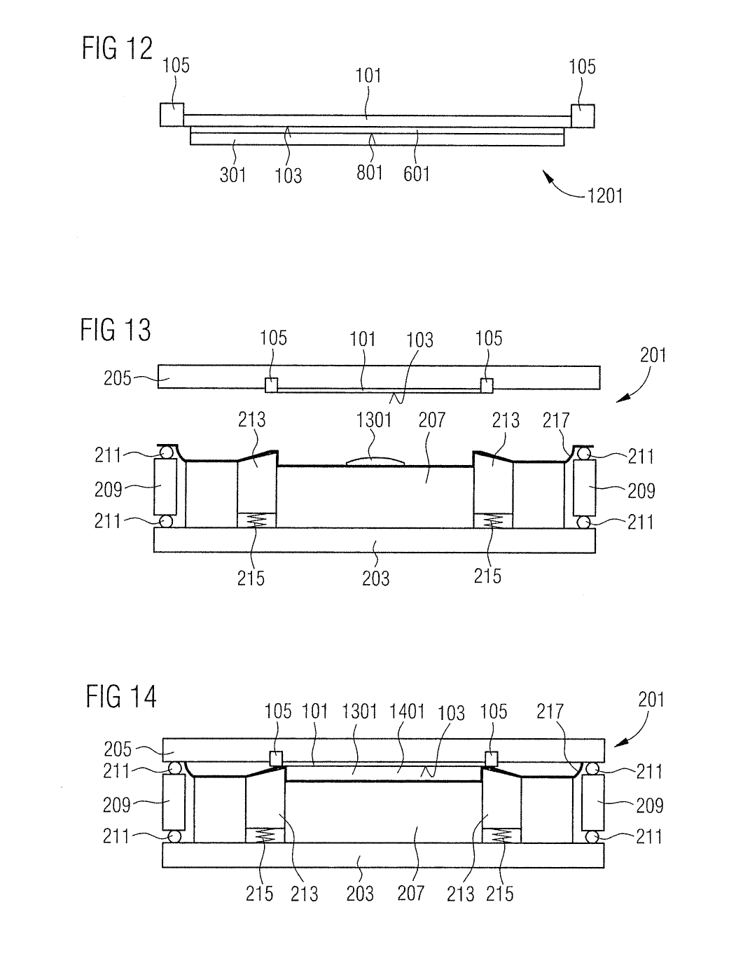

FIG. 12 shows the carrier 101 after the clamping ring 105 has been removed from the upper part 205. A layer stack is apparent, comprising the extruded diffuser layer 601 and the injection-molded conversion layer 301 which is formed on the surface 801.

Thus, a converter component 1201 is produced comprising the layer stack made up of the diffuser layer 601 and the conversion layer 301. Here as well, in an example not shown, the carrier 101 is removed from this layer stack.

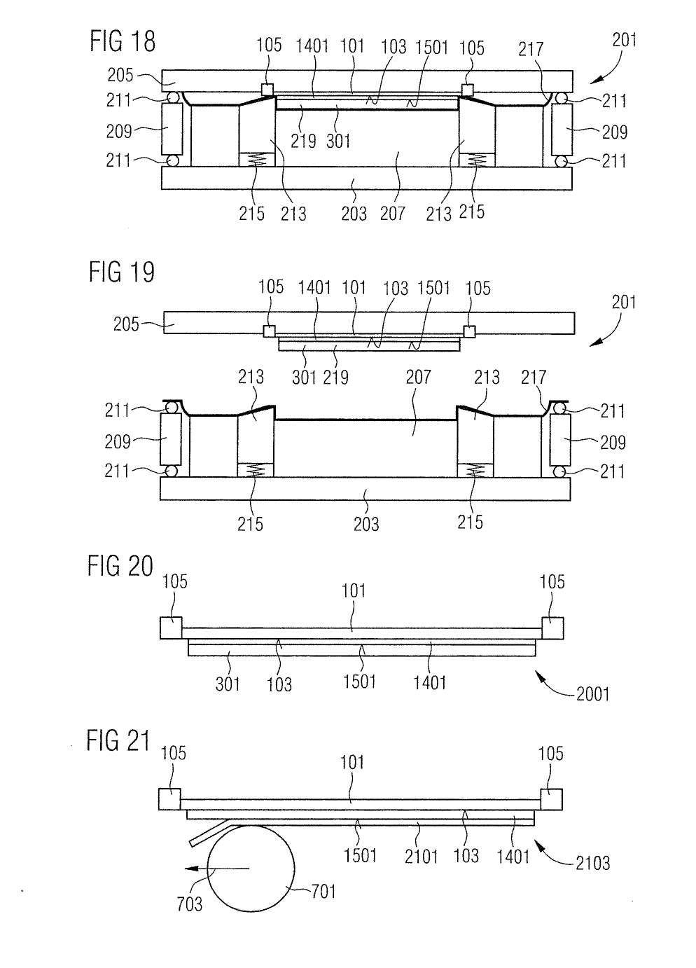

FIGS. 13 to 20 respectively show a production step in a method of producing a third converter component. This example comprises a carrier 101 clamped in a clamping ring 105, analogously to FIG. 1. Here as well, the carrier is arranged analogously to FIG. 2 in an upper part 205 of an injection-molding tool 201, as will be described further below.

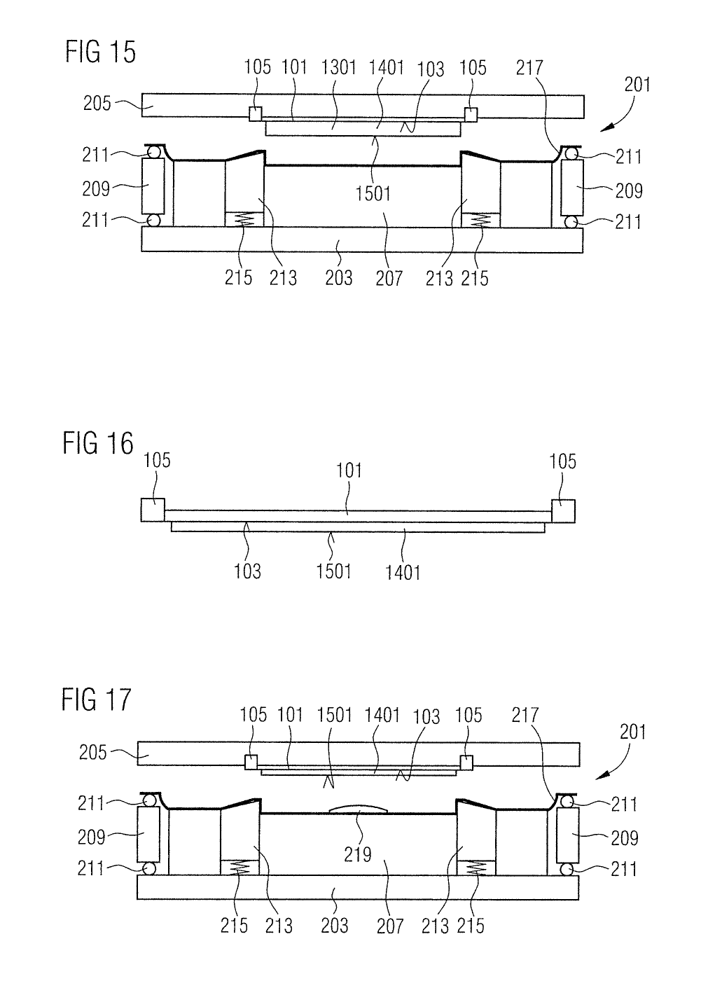

FIGS. 13 to 15 show, analogously to FIGS. 2 to 4, an injection-molding process (the corresponding examples apply analogously), wherein here, however, a diffuser layer is injection-molded, rather than a conversion layer. This means that a diffuser material 1301, rather than a conversion material 219, is applied to the anti-adhesion film 217 to form an injection-molded diffuser layer 1401 in the closed state of the injection-molding tool 201 by an injection-molding process. FIG. 15 shows the injection-molding tool 201 in an opened state, wherein the injection-molded diffuser layer 1401 is formed or arranged on the surface 103 of the carrier 101. The injection-molded diffuser layer 1401 has a surface 1501 which faces away from the surface 103.

FIG. 16 shows the carrier 101 having the injection-molded diffuser layer 1401, after the clamping ring 105 has been removed from the upper part 201.

According to FIGS. 17 to 19, an additional injection-molding process is provided, wherein this time, a conversion layer is injection-molded, analogously to FIGS. 2 to 4. This means that a conversion material 219 is applied to the anti-adhesion film 217. The carrier 101 according to FIG. 16 having the injection-molded diffuser layer 1401 is arranged on the upper part 205 of the injection-molding tool 201. The surface 1501 of the injection-molded diffuser layer 1401 thus faces the conversion material 219. Correspondingly, the conversion layer may then be injection-molded by closing the injection-molding tool 201 and the subsequent injection-molding process. This means that an injection-molded conversion layer 301 is formed on the surface 1501 of the injection-molded diffuser layer 1401, corresponding to the injection-molding process.

FIG. 20 shows the carrier 101 comprising the injection-molded diffuser layer 1401 and the injection-molded conversion layer 301, after the clamping ring 103 has been removed from the upper part 205.

Thus, a converter component 2001 is produced comprising a layer stack having the injection-molded diffuser layer 1401 and the injection-molded conversion layer 301. Here as well, in an example not shown, the carrier 101 is removed from this layer stack.

FIG. 21 shows a production step in a method of producing an additional converter component.

An injection-molding process may be provided for injection-molding a diffuser layer 1401, analogously to FIGS. 13 to 15. However, in contrast to the example according to FIGS. 17 to 20, lamination of an extruded conversion layer 2101 onto the surface 1501 of the injection-molded diffuser layer 1401 is provided, rather than injection molding of the conversion layer.

This means that the arrangement according to FIG. 16 is used to laminate the extruded conversion layer 2101 onto the surface 1501. This is analogous to FIG. 7 using a roller 701. Here as well, the extruded conversion layer 2101 has already been produced or is produced within the scope of the method.

Thus, a converter component 2103 is produced comprising a layer stack having the injection-molded diffuser layer 1401 and the extruded conversion layer 2101. Here as well, in an example not shown, the carrier 101 is removed from this layer stack.

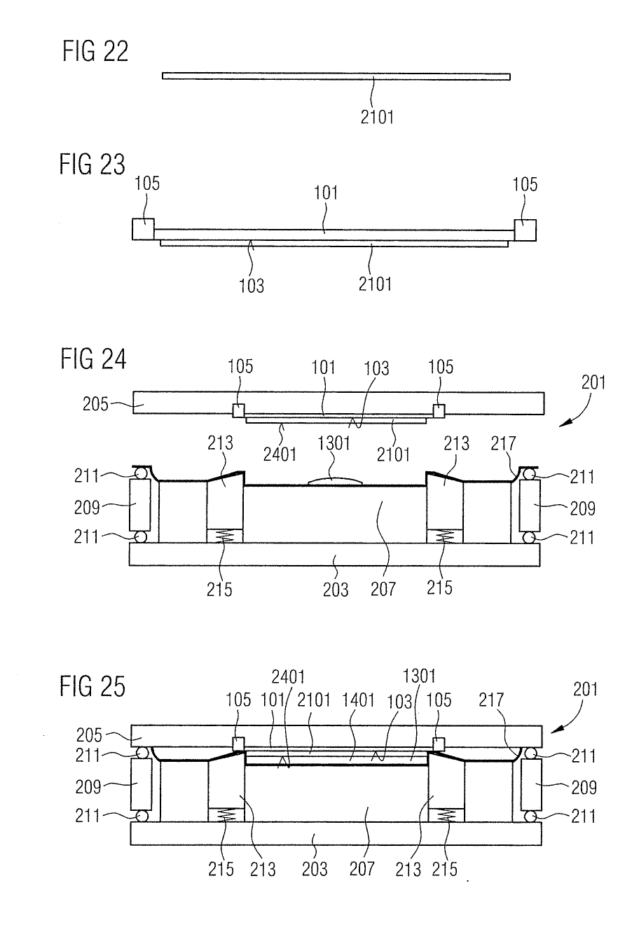

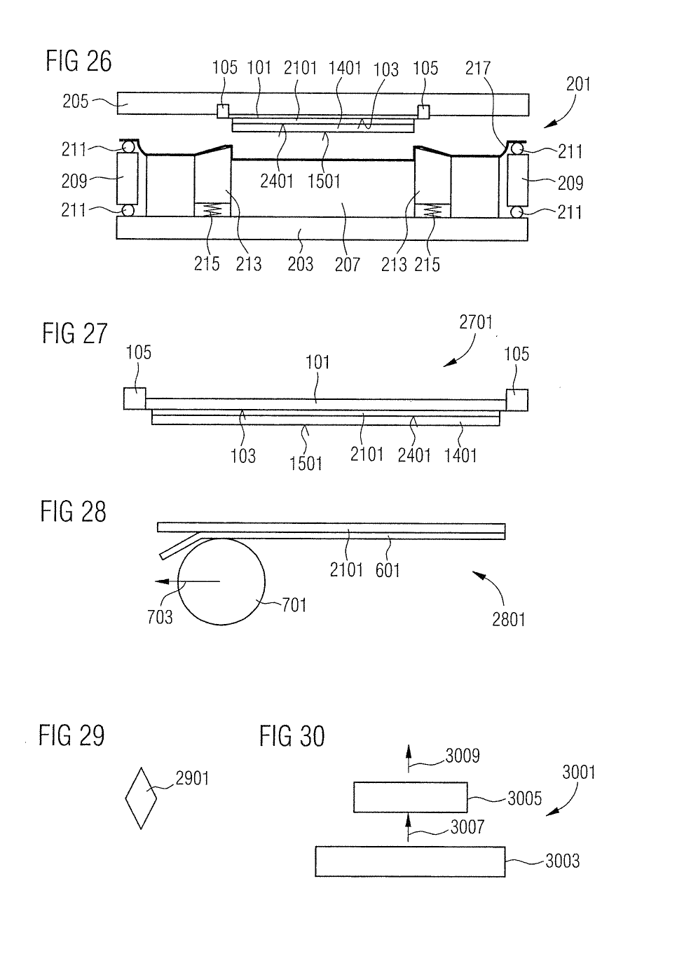

FIGS. 22 to 27 respectively show a production step in a method of producing an additional converter component.

According to FIG. 22, an extruded conversion layer 2101 is provided. The extruded conversion layer is laminated according to FIG. 23 onto the surface 103 of the carrier 101. The carrier 101, which is clamped in the clamping ring 105, wherein the carrier 101 has the laminated conversion layer 2101, is then attached to the upper part 205 of the injection-molding tool 201, according to FIG. 24. Analogously to FIGS. 13 to 15, a diffuser layer is then injection-molded. This means that a diffuser material 1301 is introduced into the injection-molding tool 201 so that within the scope of the injection-molding process, an injection-molded diffuser layer 1401 is formed on a surface 2401 of the conversion layer 2101, wherein the surface 2401 faces away from the surface 103 of the carrier 101.

FIG. 27 shows the carrier 101 having the laminated conversion layer 2101 and the injection-molded diffuser layer 1401 after the removal of the carrier 101 from the upper part 205. Thus, a converter component 2701 is produced having a layer stack comprising the conversion layer 2101 and the diffuser layer 1401. Here as well, in an example not shown, the carrier 101 is removed from this layer stack.

FIG. 28 shows a production step in a method of producing an additional converter component.

An extruded conversion layer 2101 and an extruded diffuser layer 601 may be provided, wherein these two extruded layers 2101, 601 are laminated together. This is analogous to FIG. 7 by a roller 701.

Thus, a converter component 2801 is produced comprising a layer stack having the two extruded layers 601, 2101.

In an example not shown, the above-described converter components are respectively singulated. This is carried out, for example, by sawing, water-jet cutting, laser-beam cutting, or die-cutting. In an example not shown, the singulated converter components are characterized electro-optically.

FIG. 29 shows a method of producing a converter component for an optoelectronic lighting apparatus. The method comprises the following step:
forming 2901 a layer stack having an injection-molded or extruded conversion layer and an injection-molded or extruded diffuser layer.

FIG. 30 shows an optoelectronic lighting apparatus 3001. The optoelectronic lighting apparatus 3001 comprises a light-emitting semiconductor component 3003, for example, a light-emitting diode, in particular a laser diode. The light-emitting diode is, for example, an inorganic or an organic light-emitting diode.

The optoelectronic lighting apparatus 3001 furthermore comprises a converter component 3005. This means in particular that the converter component 3005 may comprise a layer stack according to one of the above-described layer stacks.

During operation of the optoelectronic lighting apparatus 3001, the light-emitting semiconductor component 3003 emits primary light 3007. This primary light 3007 is converted into secondary light 3009 by the converter component 3005.

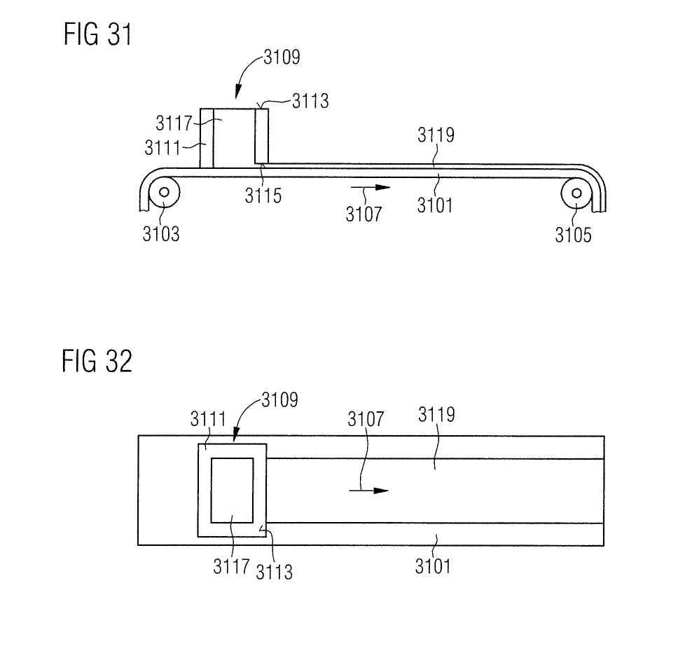

FIG. 31 shows a schematic representation of an extrusion process in a lateral sectional view.

A film 3101 is transported or drawn via two rollers 3103 and 3105 from the left to the right in the direction of the arrow 3107, with reference to the plane of the paper.

An extrusion tool 3109 is fixedly arranged between the two rollers 3103 and 3105 and above the film 301, with reference to the plane of the paper. The extrusion tool 3109 comprises a hollow body 3111 which is open on two opposite sides 3113 and 3115. The upper side 3113 faces away from the film 3101; the lower side 3115 faces the film 3101.

A conversion material 3117 is introduced into the hollow body 3111 from above via the upper open side 3113 and is thus applied to, in particular cast onto, the film 3101 via the lower open side 3115, while the film 3101 is moved in the direction of the arrow 3107 by the two rollers 3103 and 3105. As a result, an extruded conversion layer 3119 forms on the film 3101. Meanwhile, the extrusion tool 3109 is not moved, i.e., it is held fixed.

Instead of the conversion material 3117, according to one example, a diffuser material is used that, analogously to the conversion material 3117, is applied to the film 3101 via the hollow body 3111, in particular is cast onto the film 3101 so that an extruded diffuser layer forms.

A film having a conversion layer having already been applied may be moved below the extrusion tool 3111 by the two rollers 3103 and 3105 in the direction of the arrow 3107, while a diffuser material is applied via the extrusion tool 3111 to the conversion layer having already been applied so that a diffuser layer forms on the conversion layer that has already been applied. The conversion layer that has already been applied is, for example, an extruded conversion layer, for example, the conversion layer 3119.

A film having a diffuser layer hat has already been applied may be moved below the extrusion tool 3111 in the direction of the arrow 3107 by the two rollers 3103 and 3105, while a conversion material is applied to, in particular cast onto, the diffuser layer that has already been applied, via the extrusion tool 3111 so that a conversion layer forms on the diffuser layer that has already been applied. The diffuser layer that has already been applied is, for example, an extruded diffuser layer.

FIG. 32 shows a schematic representation of the extrusion process of FIG. 31 in a top view, wherein the two rollers 3103 and 3105 are not apparent due to the top view.

We thus produce a layer stack, in particular a two-layer layer stack, for a converter component, wherein this layer stack has a conversion layer and a diffuser layer. In particular particles having an average grain size of 100 nm to 10 μm are used as a diffuser for the diffuser layer. The following diffuser particles are used in particular as a material for a diffuser: SiO₂ particles, Al₂O₃ particles, TiO₂ particles, silicone particles, glass particles.

By providing such layer stacks, defined and sharp outer edges of the converter component may be obtained, at which, for example, potting compound stops within the scope of a potting process, without flowing onto the converter component.

In particular, the layers of the layer stack have a highly homogeneous thickness. This is in particular advantageous because a fluctuation in thickness within a converter component is very important. In particular if multiple semiconductor components, in particular multiple chips, respectively having a corresponding converter component on a common substrate, are filled, for example, with white potting compound, the fluctuation in thickness from converter component to converter component is crucial. Here, however, our methods have the advantage that a reproducible layer thickness of the layer stack, and thus ultimately of the converter component, are made possible due to the use of extruded or injection-molded layers.

We thus provide such layers in particular for using, for example, silicone films for the production of the layers, in particular the films, produced either via film-drawing processes, i.e., an extrusion method, or via a compression-molding process (so-called layer molding), i.e., an injection-molding method. Both processes or methods generate a highly homogeneous layer thickness and a smooth surface of the silicone films.

The following methods are in particular provided by way of example (if the term “film” is used, “layer” is always to be read; molding stands for injection molding; film drawing stands for extruding):
a) Molding (injection molding) a conversion film. Film drawing (extruding) a diffuse film (diffuser layer). Laminating the diffuse film onto the conversion film. In the compression-molding process, generally and in particular detached from this example, in particular layers having a thickness greater than 200 μm are formed to advantageously prevent the occurrence, for example, of a phosphor separation of the coarse conversion particles in the case of low layer thicknesses. This example a) was described by way of example in conjunction with FIGS. 1 to 7.
b) Film-drawing the diffuse film (diffuser layer). Molding the conversion layer onto the diffuse film. This example b) was described by way of example in conjunction with FIGS. 8 to 12.
c) Molding the diffuse film (diffuser layer). Molding the conversion layer onto the diffuse film. This example c) was described by way of example in conjunction with FIGS. 13 to 20.
d) Molding the diffuse film (diffuser layer). Film-drawing the conversion film. Laminating the conversion film onto the diffuse film. This example d) was explained by way of example in conjunction with FIG. 21.
e) Film-drawing the conversion film. Molding the diffuse layer (diffuser layer) onto the conversion film. This example e) was described by way of example in conjunction with FIGS. 22 to 27.
f) Film-drawing the conversion film. Film-drawing the diffuse film. Laminating the two films together. This example f) was described by way of example in conjunction with FIG. 28.

As a result, in particular the following advantages may be made possible:
Production of two-layer, silicone-based converter components which, for example, cause an optoelectronic lighting apparatus to have a white color impression in the deactivated state. This is in particular achieved by the diffuser layer.
In contrast to ceramic conversion layers, more, in particular all, color temperatures may be covered.
It is possible to flexibly set the layer thickness of the layer stack via the diffuse layer (diffuser layer). For example, a thin conversion layer may be provided which sits directly on the semiconductor component, for example, on the chip, to achieve good heat dissipation, and a thicker diffuse layer may be provided to generate the desired layer thickness. Here, thin means in particular 10 μm to 200 μm. This is due to the fact that, in contrast to an often-used total potting, the layers are very thin. Here, thick means in particular 10 μm to 500 μm. The layer thickness of the layer stack is a function in particular of the design of the converter component and/or the lighting apparatus. In the two-layer systems described here, the converter particles in the conversion layer are tightly packed on the light-emitting surface of the optoelectronic component, thus advantageously achieving good heat dissipation. The diffuser layer must then, so to speak, only fill up to the desired overall layer thickness. This is in contrast to conversion elements made up of only one layer. In such one-layer conversion elements made up of only one layer, it is the case that the converter particles are in a very loose composite, which does not achieve very good heat dissipation.
Via the (for example, smooth) diffuse layer above the conversion layer, a highly homogeneous, in particular white appearance of the converter component may be generated.
Necessary rebonding steps which are required, starting with the production of the silicone films (generally the layer stack), continuing with the singulation, and concluding with the bonding of the converter component to the chip, are considerably simplified by the smooth surface of the layer stack on opposite sides (diffuse film side and conversion film side).
By sawing or laser cutting, very sharp converter component outer edges may be generated, which make possible a potting process, for example, up to the converter layer upper edge or diffuser layer upper edge. As a result, an LED flash component may be produced which, for example, appears completely white in the deactivated state.
As a result of the very slight fluctuations in thickness from a layer stack of one converter component to another layer stack of another converter component, a common potting process of complete panels of converter components up to the converter component upper edges is possible.

Although our methods have been illustrated and described in greater detail via the preferred examples, this disclosure is not limited by the disclosed examples, and other variations may be derived from it by those skilled in the art, without departing from the protective scope of the appended claims.

This application claims priority of DE 10 2015 106 865.6, the subject matter of which is incorporated herein by reference.

1-13. (canceled)

14. A method of producing a converter component for an optoelectronic lighting apparatus comprising:
forming a layer stack having an injection-molded or extruded conversion layer and an injection-molded or extruded diffuser layer.

16. The method according to claim 14, wherein, to form a layer stack having an injection-molded conversion layer and an extruded diffuser layer, a conversion material is arranged on a surface of a carrier by injection molding to form an injection-molded conversion layer arranged on the surface of the carrier, and an extruded diffuser layer is laminated onto the injection-molded conversion layer arranged on the surface of the carrier.

16. The method according to claim 14, wherein, to form a layer stack having an injection-molded conversion layer and an extruded diffuser layer, an extruded diffuser layer is laminated onto a surface of a carrier, and a conversion material is arranged by injection molding on the diffuser layer laminated on the surface of the carrier to form an injection-molded conversion layer arranged on the diffuser layer.

17. The method according to claim 14, wherein, to form a layer stack having an injection-molded conversion layer and an injection-molded diffuser layer, a diffuser material is arranged on a surface of a carrier by injection molding to form an injection-molded diffuser layer arranged on the surface of the carrier, and a conversion material is arranged by injection molding on the injection-molded diffuser layer arranged on the surface of the carrier to form an injection-molded conversion layer arranged on the diffuser layer.

18. The method according to claim 14, wherein, to form a layer stack having an extruded conversion layer and an injection-molded diffuser layer, a diffuser material is arranged on a surface of a carrier by injection molding to form an injection-molded diffuser layer arranged on the surface of the carrier, and an extruded conversion layer is laminated onto the injection-molded diffuser layer which is arranged on the surface of the carrier.

19. The method according to claim 14, wherein, to form a layer stack having an extruded conversion layer and an injection-molded diffuser layer, an extruded conversion layer is laminated onto a surface of a carrier, and a diffuser material is arranged by injection molding on the conversion layer laminated on the surface of the carrier to form an injection-molded diffuser layer arranged on the conversion layer.

20. The method according to claim 15, wherein, after formation of the layer stack, the carrier is removed from the layer stack.

21. The method according to claim 15, wherein the carrier is formed as a carrier film.

22. The method according to claim 14, wherein, to form a layer stack having an extruded conversion layer and an extruded diffuser layer, an extruded conversion layer and an extruded diffuser layer are laminated together.

23. The method according to claim 14, wherein the diffuser layer comprises one or multiple diffuser particles selected from the group consisting of SiO₂ particles, Al₂O₃ particles, TiO₂ particles, silicone particles and glass particles.

24. The method according to claim 14, wherein at least one of the two layers comprises silicone.

25. A converter component for an optoelectronic lighting apparatus comprising:
a layer stack including
an injection-molded or extruded conversion layer, and
an injection-molded or extruded diffuser layer.

26. An optoelectronic lighting apparatus comprising:
a light-emitting semiconductor component, and
the converter component according to claim 25.
